(19) United States
(12) Patent Application Publication
(10) Pub. No.: US 2002/0186324 A1
(43) Pub. Date: Dec. 12, 2002

(54) Systems and methods for combining analog set-top box converters with digital set-top box converters

(76) Inventor: Alex Cheng, Valencia, CA (US)

Correspondence Address: Robert J. Depke, MAYER, BROWN & PLATT, P.O. Box 2828, Chicago, IL, 60690-2828, US

(21) Appl. No.: 09/877,458

(22) Filed: Jun. 8, 2001

(51) Int. Cl. H04N 7/16; H04N 7/00; H04N 11/00; H03M 1/12; H04N 5/268; H04N 5/44

(52) U.S. Cl. 348/706; 348/468; 348/572; 348/725; 348/705

(57) ABSTRACT

Systems and methods provide for interconnection of existing analog set-top box signal conversion hardware with new digital only set-top box conversion systems. In accordance with an exemplary embodiment of present invention, the digital and analog set-top boxes each respectively provide both video and stereo audio outputs which feed a relay or switch. In the preferred exemplary embodiment, the relay or switch is a smart switch which is configured to connect and output from the appropriate decoder or demodulator based on the user's channel selection. The output from the switch feeds a cable subscribers television. Additionally, a variety of different structures and methods are disclosed for connection of digital set-top boxes with analog demodulation hardware.

### BACKGROUND OF INVENTION

1. Field of Invention

The present invention relates generally to the field of telecommunications. More specifically, the present invention is directed to systems and methods for combining new digital set-top boxes with existing analog hardware in order to provide both analog and digital signal conversion capability for cable television transmissions.

2. Description of the Related Art

The cable television industry is currently in transition, moving from all analog transmission of programming information to an all-digital transmission. This transition phase will take several years to complete. In the interim, some programming will be transmitted in analog modulation format while the remaining portion will be transmitted in digital format. In light of the fact that some programming is in analog format and the remaining in digital, it is necessary that subscribers have the ability to demodulate both analog and digital signals.

At the end of the year 2000, about 10 million digital set-top boxes had been installed in the United States. However, there are still more than 50 million cable subscribers in the United States who do not yet have digital set-top boxes. These cable subscribers continue to rely upon analog set-top box converters. At the current deployment rate, the cable industry will operate in a mixed analog and digital environment for at least another 5-10 years.

The current replacement of analog set-top boxes with new digital set-top boxes currently typically also includes the complete replacement of all the circuitry necessary for demodulation of analog transmission signals. An exclusively digital solution is currently not possible because it is necessary to accommodate both programming formats which will exist during the transition period. A set-top box which only provided digital conversion circuitry would be incapable of decoding or demodulating analog transmissions.

Because cable companies are required to provide both digital and analog conversion capability during the transition phase, the cable companies must provide some mechanism for decoding or demodulating both types of signals. Thus, the current solution is to provide a new set-top box which includes circuitry for converting analog signal transmissions and additional circuitry for converting digital signal transmissions. There is currently no digital set-top box available which is compatible with existing analog hardware in order to provide conversion of both types of transmission formats.

One problem with the current solution of providing new set-top box converters that have conversion capability for both analog and digital transmissions is that the cable industry has already paid for all of the existing analog set-top box systems which each include all the required hardware for converting and demodulation of analog cable transmission programming. The current solution of providing a single new set-top box which includes circuitry for converting both analog and digital signals basically discards this investment by failing to utilize existing hardware for the conversion of analog signals.

One proposed alternate solution is to provide new set-top boxes which only include circuitry for converting digital signals. This is accomplished by duplicating all the analog transmission channels with a redundant set of digital transmission channels. In accordance with this proposed solution, all programming information is transmitted in both analog and digital format during the transition period. However, there are two substantial problems with this digital-only set-top box approach. The first is the cost of duplicating the equipment which is necessary in order to accommodate dual transmission. The cost of duplicating an analog channel in digital format is about $50,000 per channel at each cable head end. This cost alone is so significant that it virtually eliminates this proposal as a possible solution.

The second problem with this proposed solution is bandwidth limitations. This proposed solution takes up a substantial portion of the overall available bandwidth by transmitting the same information through multiple bandwidth segments. The ever increasing demand placed on existing bandwidth has also substantially eliminated this proposed solution as a possibility.

Yet another alternate solution is to provide a digital set-top box whose video and stereo audio outputs are provided as inputs to an RF modulator. The RF modulator essentially converts the digitally converted video and stereo audio into another analog RF signal. This analog RF signal output from the converter is in turn supplied to an RF combiner which also receives an input from the cable source. The output of the combiner then feeds an input of a conventional analog set-top box where it is subsequently converted for display through a television. Through this solution, a cable subscriber is able to convert all of the analog and digital channels with the original analog set-top box.

One problem with this proposed solution is that it requires two set-top boxes which take a valuable real estate at the home of the cable subscriber. Most cable subscribers do not like this proposed solution. Another problem is that this solution requires that a cable subscriber use two remote controllers, one for each set-top box. Furthermore, operation can be confusing. If a user intended to select an analog channel, the user would enter a channel with the analog controller. Alternatively, if the user intended to select a digital channel, the user would first be required to select the unused analog channel on which the digital signals were received and thereafter use the digital controller to select the desired digital channel. Furthermore, with this proposed solution, the electronic programming guide as well as any other digital services provided through the cable television network cannot be accessed directly through the digital set-top box without first manually turning the channel to the externally modulated digital channel on the analog remote.

In light of these shortcomings, there are currently no existing practical or acceptable solutions for combining new digital set-top boxes with existing analog hardware in order to make a combined system which is capable of demodulating or decoding both analog and digital transmission signals while making use of existing analog hardware.

However, in the satellite industry, a mechanical A/B switch has been incorporated into a digital only set top box recently for manually switching between the signals of the analog and digital set top box. The main difference between the old C-band satellite system with the cable is that the tuning time from one satellite to another is usually several minutes, and manual fine tuning of the receiver is often required, so the A/B switch solution is not too outrageous for the C-band satellite viewers. But the same cannot be accepted by most cable subscribers.

Accordingly, there remains a need in the art for improved systems and methods for converting both analog and digital cable transmission signals which do not require additional hardware for conversion of analog signals. Additionally, there remains a need in the cable industry for novel systems and methods for interconnection of analog and digital demodulation equipment.

### SUMMARY OF INVENTION

The present invention overcomes the shortcomings of the prior art and provides novel systems and methods for interconnection of existing analog set-top box signal conversion hardware with new digital only set-top box conversion systems. In accordance with an exemplary embodiment of present invention, a cable subscriber line feeds both an existing analog set-top box conversion system as well as a new digital converter. The digital and analog set-top boxes each respectively provide both video and stereo audio outputs which feed a relay or switch.

In the preferred exemplary embodiment, the relay or switch is a smart switch which is configured to automatically connect an output from the appropriate decoder or demodulator based on the user's channel selection. The output from the switch in turn feeds a television set. In the preferred exemplary embodiment, a database or other memory storage provides a correlation between user channel selections and the appropriate decoder or demodulator selection. A microprocessor or CPU is programmed to access information contained in the memory and control the switch accordingly based on user selection. Those skilled in the art will appreciate that alternate hardwired solutions which do not use a microprocessor are also possible but less desirable.

Through this system, converted signals from each of the different types of set-top boxes are available to a cable subscriber. In the preferred embodiment, The digital converter outputs will be connected to the normally closed poles of the switch and the analog outputs will be connected to the normally open poles. After transition to digital only transmission is completed for a system, the analog set-top box converter may be removed or simply powered down. Those skilled in the art will recognize that other switching mechanisms can easily be used as a substitution for the switch or relay selected for the preferred exemplary embodiment.

In the preferred exemplary embodiment, the firmware inside the digital set-top box may be programmed to select between either analog or digital signals based on user selected channel number, as noted. For example, one cable system operator can set channels 1-99 as the system's analog channels and all channels above 100 as the digital channels. Another system user can set channels 1 to 40 as the analog channels and anything above channel 40 will be considered to be digital transmissions. In this way it is very easy to program the system to determine how to trigger the relay or switch appropriately. Obviously, through utilization of a database or other memory construct it is possible to interleave both the analog and digital channels while still being able to accurately choose the appropriate decoder or demodulator.

This solution is viable due to the fact that the analog channel numbers are fixed to corresponding frequencies. Other digital channel numbers used by the system are virtual numbers and they do not have the frequency to channel number relationships like the analog channels, this means that analog channel can be converted to digital and all have totally different channel numbering.

In the preferred exemplary embodiment, the firmware for operation of the relay or other switching circuitry can be loaded into flash memory of the system so that the channel provisioning program can be downloaded and changed as desired. Changes would occur whenever an existing analog transmission format is changed to digital. A CPU or microprocessor is preferably used to control the relay or switching mechanism in order to effect end-user channel selection.

In an alternate exemplary embodiment of the present invention, the switch provides both primary and secondary outputs. In this configuration, a cable subscriber is able to select either an analog or digital channel for immediate viewing and/or recording via a primary output from the switch. The user is also able to choose a secondary output which can be used in order to provide picture-in-picture information and/or an input to a further recording device Through this configuration a user is able to simultaneously access any programming information on one digital and one analog channel. This alternate configuration adds additional versatility and functionality to the overall system.

In yet another alternate configuration, the new digital set-top box or other hardware provides an analog to digital converter for conversion of the stereo audio and video outputs from the original analog set-top box. The output of the analog to digital converter is provided as an input to a two-pole relay. The two-pole relay also preferably receives an alternate input from the new digital converter. Specifically, in the preferred embodiment, the signal comes from the MPEG decoder of the new digital set-top box.

This two-pole switch provides similar functionality to the smart switch discussed previously. In particular, the switch is able to select the appropriate input source for the switch output based on user defined channel selection and correlation of the channel selection with the appropriate source contained in a database or other memory storage. The database may be embodied as any known conventional database or memory storage such as, for example, linked lists and the like.

In this embodiment, the output from the two-pole relay or switch is then subsequently processed as any other digital signal in a digital set-top box. In the preferred exemplary embodiment, an image scale circuit is provided as well as an image composition circuit for incorporation of graphics information from a graphics unit. Thereafter, the information is subsequently converted back to an analog signal and processed through an NTSC modulator. An output driver thereafter provides stereo audio and video outputs as inputs to a television set.

In an alternate refined embodiment of this design, the two-pole relay provides both primary and secondary outputs. Accordingly, transmissions from one analog and one digital channel may be made available simultaneously. The user may choose between display of one and recording of the other, or simultaneous display of both via picture-in-picture circuitry.

### BRIEF DESCRIPTION OF THE DRAWINGS

FIG. 1 illustrates an exemplary embodiment of the present invention;

FIG. 2 illustrates an alternate exemplary embodiment of the present invention;

FIG. 3 illustrates an alternate exemplary embodiment of the present invention;

FIG. 4 illustrates an alternate exemplary embodiment of the present invention;

FIG. 5 illustrates an alternate exemplary embodiment of the present invention; and

FIG. 6 illustrates an alternate exemplary embodiment of the present invention.

### DETAILED DESCRIPTION OF THE PRESENTLY PREFERRED EMBODIMENTS

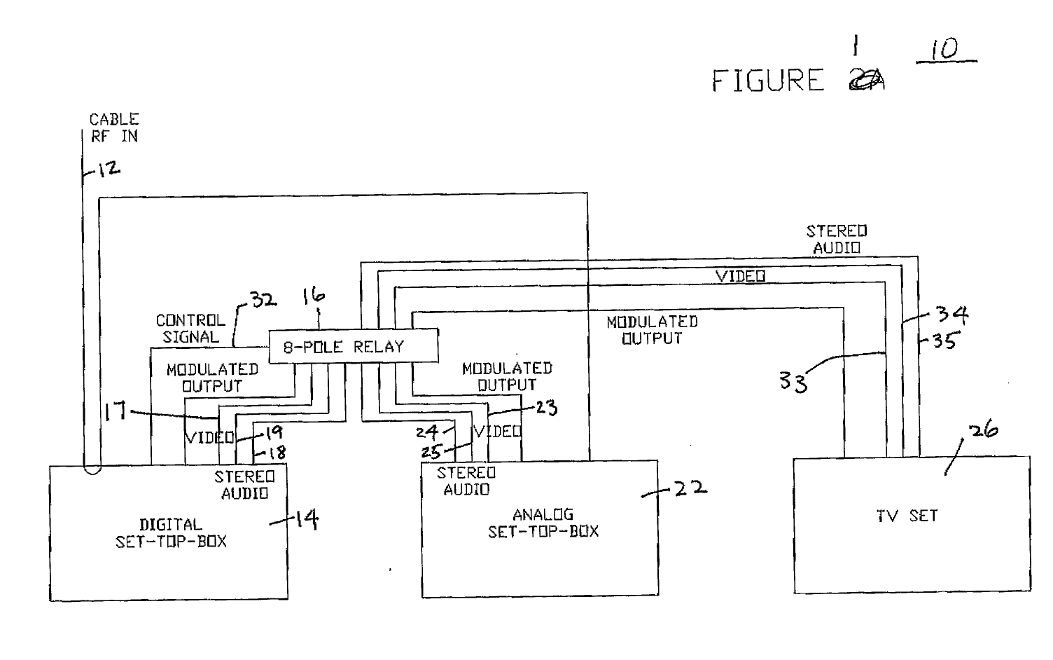

FIG. 1 illustrates a first exemplary embodiment of the present invention which is shown generally at 10. As shown in FIG. 1, a cable RF input 12 feeds a digital set top box 14. The digital set top box 14 has no internal circuitry for the conversion of received analog signals. The converted outputs from digital set top box 14 feeds an 8-pole relay or switch 16. In particular, demodulated video and stereo audio outputs 17, and 18-19 respectively feed three of the inputs to the 8-pole relay. The 8-pole relay allows switching of video and two stereo audio channels as well as a modulated RF output. It is not necessary to transfer to the modulated output and a six-pole switch could be used alternatively. The RF cable input 12 loops out from digital set-top box 14 and also feeds an analog set top box 22.

The analog set top box 22 is preferably the original analog conversion hardware provided at a user or subscriber location. The analog set top box converts analog signals it receives from RF cable input into video and stereo audio outputs. The converted video 23 and stereo audio outputs 24-25 also feed the 8 pole relay 16. The outputs from the 8-pole relay 16 in turn is transmitted to a television set 26.

Advantageously, through this interconnection of the digital and existing analog hardware, a cable television subscriber is able to convert digital programming as well as analog programming without necessitating the purchase of additional analog conversion hardware. The existing analog hardware may be utilized for conversion of analog signals while a digital-only converter is present in the new set-top box.

Operation of the system is as follows. The user may select for viewing either an analog or digital channel by entering a numerical selection into a remote control unit. In accordance with the preferred exemplary embodiment, a remote control unit, which has not been shown for the sake of convenience, provides user specified channel selection information. This information is transmitted to a microprocessor unit which has access to a memory storage unit. The memory storage unit has a database or linked list which correlates user-selected channels with information concerning whether the channel is currently transmitted through the cable system in either analog or digital format.

Depending upon whether the selected channel is an analog or digital transmission channel, the switch or relay 16 will connect the output from the appropriate box to the input of the television set, depending upon which transmission type is provided in the cable system. Specifically, those skilled in the art will recognize that either the user or the cable television system operators will have information concerning the transmission formats of various channels. The user or cable system operator is able to program the database or memory such that the switch actively chooses the appropriate digital or analog conversion unit, depending upon the known transmission format for each of the channels available through the cable system.

In a preferred exemplary embodiment of the present invention, the digital set top box has a control signal output 32 which feeds either the 8-pole relay directly or, alternatively, the memory unit which contains the correlation information.

The control signal output 32 from the digital set top box 14 advantageously allows the cable system operators to transmit a control signal indicative of a change in the information concerning transmission formats of various stations. Accordingly, the cable system operator is able to remotely change channel designations from analog to digital whenever such a change occurs. Specifically, the system operator transmits a signal which updates the memory such that an analog channel which has just been converted to digital format will select the digital converter upon user selection of the former analog channel.

For example, if channel 50 is initially an analog transmission, and the channel converts into a digital transmission format, the cable system simply transmits a signal which can be received by one or a plurality of digital set top boxes which recognizes that a control signal should be generated to adjust the database or memory such that selection of channel 50 results in switching of the digital set top box.

FIG. 1 also illustrates that in the preferred exemplary embodiment, the primary video 33 and stereo audio 34, 35 outputs directly feed a television set 26. Those skilled in the art will recognize that an additional secondary video and stereo audio output may be provided from the switch in order to provide an input to either a picture in picture input or alternatively a video cassette recorder.

In particular, the embodiment shown in FIG. 1 may be modified such that the switch provides an alternate secondary output which is the converted video or stereo audio output from either the analog or digital set-top box. In this alternate embodiment, a user is able to watch and/or record a transmission from a primary selection while also either viewing through a picture-in-picture viewer or recording a secondary transmission which is decoded or demodulated by either the digital or analog set-top box. The secondary selection in this embodiment may only be selected from one of the channels provided through the converter box which does not provide the primary transmission.

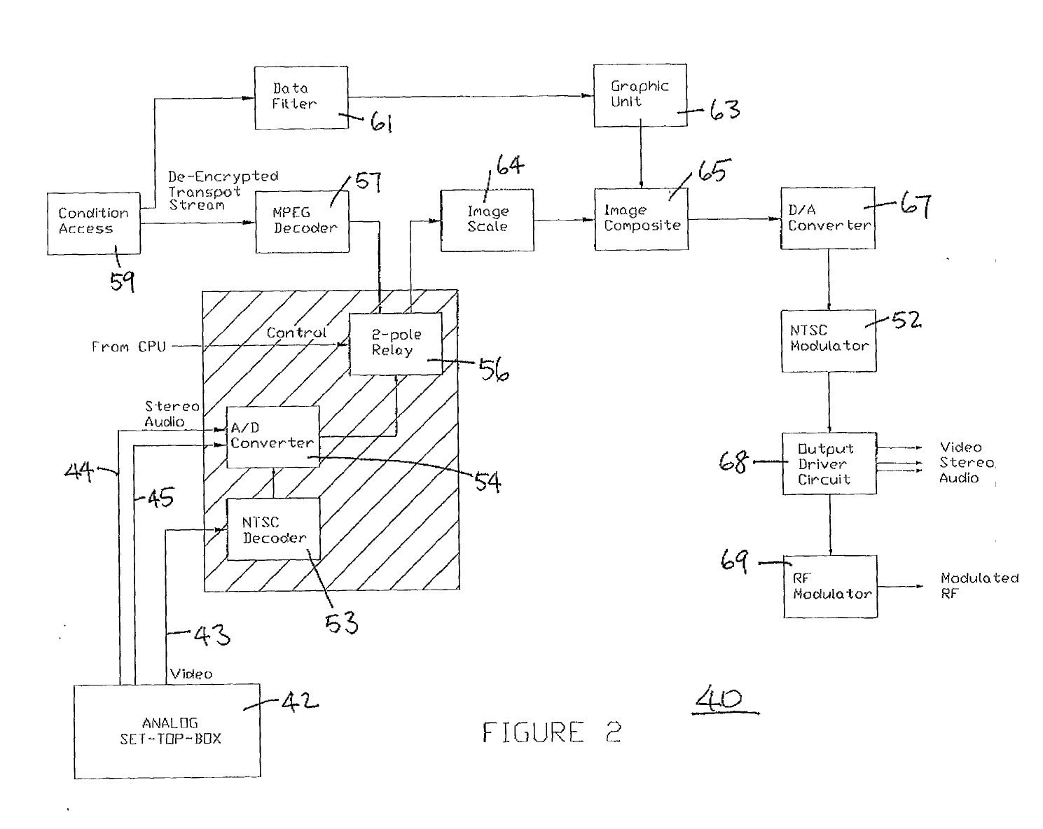

FIG. 2 illustrates another alternate exemplary embodiment of the present invention which is shown generally at 40. As shown in FIG. 2, an analog set top box 42 provides video 43 and stereo audio 44, 45 outputs that in turn feed additional circuitry of the new digital set top box. The output from the analog set top box video 43 supplies an input to an NTSC decoder 53. The stereo audio outputs 44, 45 feed A-D converter 54 which also receives an output from the NTSC decoder 53. A 2-pole relay or other switching mechanism 56 receives an output from the A-D converter 54 as an input. The two-pole relay or other switching mechanism 56 also receives an output from an MPEG decoder 57 of the digital conversion circuitry. Those skilled in the art will appreciate that the MPEG decoder 57 is a conventional source for generating a combined stream of digital video and stereo audio information in a digital set-top box. It should be recognized that the switch 56 need only provide the ability to selectively switch between output from the original analog box and the new digital conversion circuitry. The specific format of this information or point in the conversion chain which is a source input to switch is not particular relevant. It is, however, preferred that the MPEG decoder 57 provide this signal. Obviously, should the demodulation circuitry change, the source for the switch will change as well.

The 2-pole relay selectively chooses between the MPEG decoder 57 and the A-D converter 54, which receives and converts outputs from the original analog set-top box 42, in order to selectively apply either an analog converted signal or a digital converted signal as an output for display through a television. A conditional access circuit 59 provides an input to the MPEG decoder 57. The output from conditional access circuit 59 is a decoded stream of data bits. This stream also feeds filter 61 which has an output that also feeds an input to graphic unit 63. The graphic unit 63 is used for generating video image information from graphics or text data input. Those skilled in the art will appreciate that these elements form portions of a conventional circuit for performing demodulation of a digital cable signal. The relay or switch for selectively choosing between input from an analog set-top box or digital conversion circuitry is unique.

The output from the 2-pole relay feeds an image scale circuit 64. The image scale circuit 64 has an output which feeds the input of an image composite circuit 65. The image composite circuit 65 combines video information from graphic unit 63 as well as image scale unit 64.

The image composite circuit 65 feeds an input of a D-A converter 67. The D-A converter unit 67 feeds an input to the NTSC modulator 52 which has been previously described. The NTSC modulator 52 has an output which feeds an input of an output driver circuit 68 and the output driver circuit 68 provides video and stereo audio outputs for input to a television set. The video and stereo audio outputs which are input of the television set originate with either the analog set-top box 42 or the digital conversion circuitry such as, for example, MPEG decoder 57. The ultimate source simply depends upon user selection which is entered in the preferred embodiment through a remote control unit as well as the programming of relay or switch 56. Programming of the relay or switch and corresponding memory is accomplished as in the previously described embodiments. Additionally, in the preferred exemplary embodiment, an RF modulator 69 receives an input from the output driver circuit 68 and provides a modulated RF output.

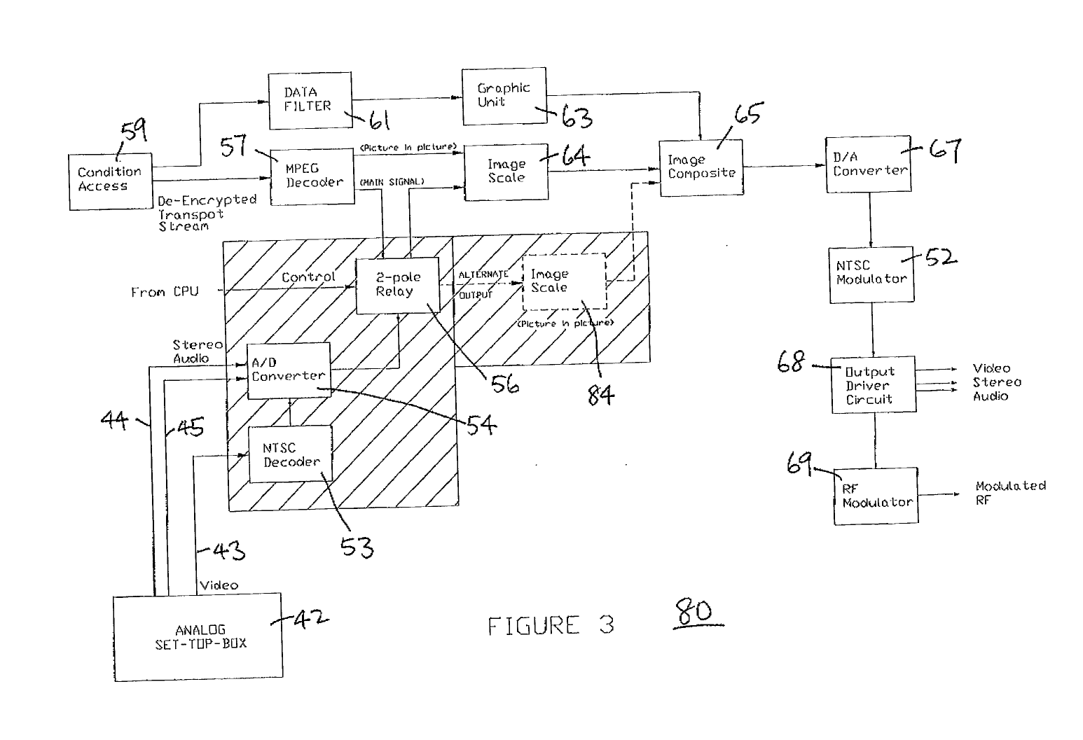

FIG. 3 illustrates yet another alternate exemplary embodiment of the present invention which is shown generally at 80. The embodiment illustrated in FIG. 3 is similar to the embodiment of FIG. 2. Accordingly, identical reference numbers have been utilized where appropriate. There are some significant differences, however, relating to the interconnection of the various elements as shown. This alternate configuration in conjunction with additional elements allows a cable subscriber utilizing the system to utilize both primary and secondary outputs. This is similar to the alternate configuration described above wherein a secondary output from the decoder which is not utilized as the primary source may be used to provide an alternate source of video and stereo audio for either recording and/or picture-in-picture viewing.

As shown in FIG. 3, the analog set top box 42 provides stereo and video audio outputs 43, 44, 45. The video output 43 feeds an NTSC decoder 53. The stereo audio outputs from analog set-top box converter 42 feed an input of an A-D converter 54. An output from the NTSC decoder also feeds an input for the A-D converter. As a result, the A/D converter is able to provide a digital stream of combined video and stereo audio information for a channel of the analog set-top box.

The output from A/D converter 54 feeds an input to a 2-pole relay 56. As in the prior embodiment described with reference to FIG. 2, 2-pole relay also receives an output from an MPEG decoder 57 which in turn receives an input from a conditional access circuit 59 of the digital set top box to the conversion circuitry. The 2-pole relay selectively provides an output which is either the digital data from the MPEG decoder of the digital set-top box or digitally converted data which originated from the analog set-top box 42 which is converted by the A-D converter 54. The primary output from this 2-pole relay is an input to a primary image scale circuit 64. The primary image scale circuit 64 also feeds an input to the image composite unit 65.

In order to provide a secondary source of video and stereo audio information in this exemplary embodiment, a secondary image scale circuit 84 is provided. The secondary image scale circuit 84 also has an output which feeds the image composite circuit 65. Those skilled in the art will recognize that this interconnection provides the ability to simultaneously view two channels through, for example, picture-and-picture image generating circuitry. As in the prior embodiment D/A converter 67 receives an input from image composite unit 65. The output of the D/A converter 67 feeds an input to NTSC modulator 52. The NTSC modulator 52 feeds output driver circuit 68 which provides video and stereo audio signals for a television (not shown). RF modulator 69 also provides a modulated RF output.

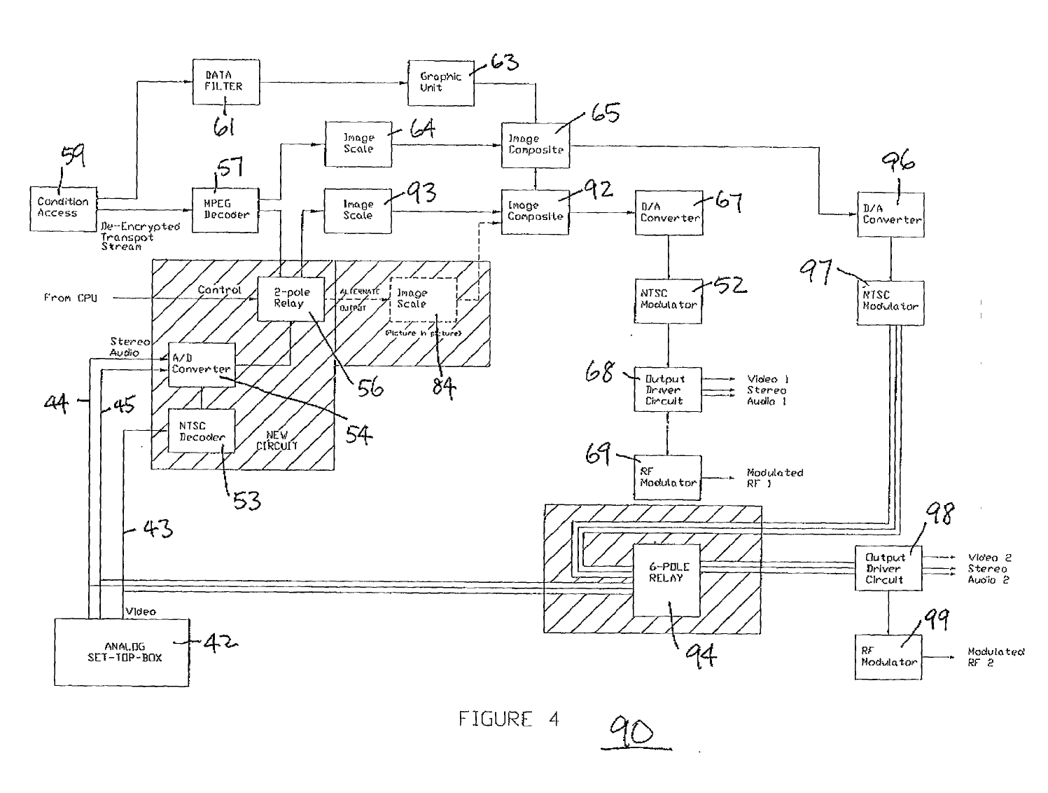

FIG. 4 illustrates yet another alternate exemplary embodiment of the present invention which is shown generally at 90. The embodiment illustrated in FIG. 4 is similar to the embodiment of FIGS. 2 and 3. Accordingly, identical reference numbers have been utilized where appropriate. This alternate exemplary embodiment provides additional functionality. In this exemplary embodiment, the video and stereo audio outputs from analog set-top box 42 are input to a 6-pole relay or switching mechanism 94. The switch 94 selectively applies its signal inputs to output driver circuit 98.

The video and stereo audio outputs from analog set-top box 42 also feed the A/D converter 54 and the NTSC decoder 53. These connections are similar to those described in FIG. 3. This embodiment also provides the alternate image scale unit 84 for receiving a secondary output from two-pole relay 56. Another difference in this embodiment is that to image scale unit 64, 93 are utilized in addition to the secondary image scale unit 84. The two image scale units 64 and 93 may be utilized to provide decoding of two separate digital channels as is known in the art. The first image scale unit 64 has an output which feeds an input to image composite circuit 65. The second image scale unit 93 has an output which feeds image composite 92. Image composite 65 has an output which feeds the D/A converter 96 and image composite 92 has an output which feeds an input of D/A converter 67. Image composite unit 92 also receives an input from alternate or secondary image scale unit 84. Accordingly, image composite 92 can provide a composite image of one signal converted by the digital converter as well as one signal converted originally by the analog set-top box. Image composite unit 65 produces yet additional video and stereo audio information.

In this embodiment, D/A converter 67 provides an input to NTSC modulator 52 which has an output that feeds output driver circuit 68. Output driver circuit 68 provides video and stereo audio information. This video and stereo audio information can be either an analog channel or a digital channel depending upon user selection. Additionally, as noted, this video and stereo audio information provided on the output of the output driver circuit 68 can provide a composite image of one digital channel and one analog channel.

Image composite 65 has an output which feeds D/A converter 96 which has an output that feeds NTSC modulator 97. Only a digital transmission channel may be processed through NTSC modulator 97. The video and stereo audio outputs from NTSC modulator 97 also provides inputs to six-pole relay 94. Six-pole relay 94 selectively applies either a signal from a digital transmission channel which is provided by NTSC modulator 97 or alternatively a signal from an analog channel as provided by analog set-top box 42. Output driver 98 receives the video and stereo audio outputs from six-pole relay 94 and provides them as secondary video and stereo audio outputs. Those skilled in the art will recognize that this configuration provides yet additional functionality for the overall system.

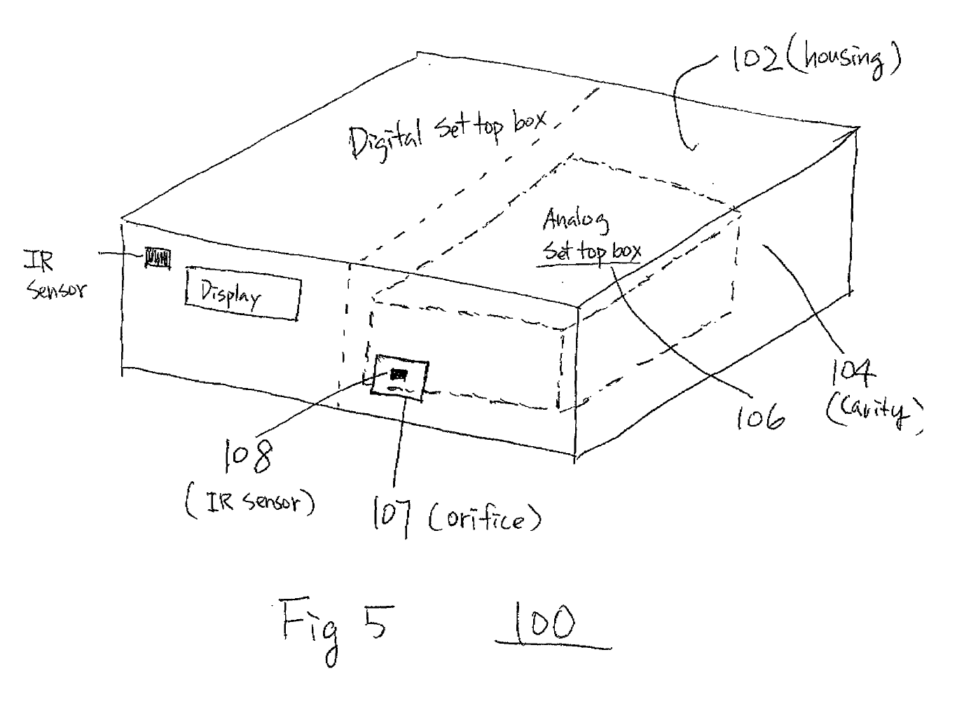

FIG. 5 illustrates an exemplary embodiment of a housing for a new digital set top box manufactured in accordance with the present invention which is shown generally at 100. In accordance with this exemplary embodiment, a housing 102 includes a cavity 104 for receiving an existing conventional analog set top box 106. The housing includes an orifice 107 which is dimensioned and aligned with the infrared receiving element 108 of the analog set top box such that the infrared receiving element 108 is located in or near this orifice 107. This allows a user to transmit infrared remote control signals to the infrared receiving element 108 of the analog set-top box.

Advantageously, the housing 102 incorporates the necessary structures for implementation of the digital portion of the set top box and also provides a cavity for receiving the conventional analog set top box 106 in a single unit. Wiring connections between the two structures can be readily made. Advantageously, this design not only saves space but also enables the use of a single remote control unit to control both the new digital conversion elements of the new set top box as well as the existing analog conversion device. In accordance with this exemplary embodiment, the manufacturer of the digital set top box and housing 102 with cavity for receiving an existing analog set top box manufactures the housing in accordance with the dimensions of the existing analog hardware. Additionally, based on convention, the manufacturer is able to determine the particular signaling protocol for the infrared signal transmissions in the existing analog set top box. As a result, the system is able to use a single remote control unit which is capable of controlling both the new digital set top box portion as well as the existing analog set top box. Specifically, for example, the system may be configured to receive various signals for controlling the digital set-top box functions. In light of information concerning the analog set-top box remote control signaling, the digital set-top box and its remote control unit can be configured to use signals which are not recognized by the analog unit for controlling the digital set-top box. The new single remote control unit can also be configured to use the existing analog set-top box signaling protocols whenever user selects an analog channel for viewing.

One of the shortcomings of this design is that the manufacturer must design and develop a number of different digital set-top boxes in order to accommodate each of the different manufacturers designed for the various models of existing analog set-top box hardware. Specifically, those skilled in the art will appreciate that there are currently a variety of existing designs for the physical dimensions of the existing analog set-top boxes as well as the location of the infrared receiving element in these units. As a result, in order to provide a new digital set-top box in accordance with this exemplary embodiment which is compatible with each of these units, the manufacturer must design and develop several different new digital only set-top boxes to accommodate these various existing designs. The alternate exemplary embodiment described below overcomes these deficiencies.

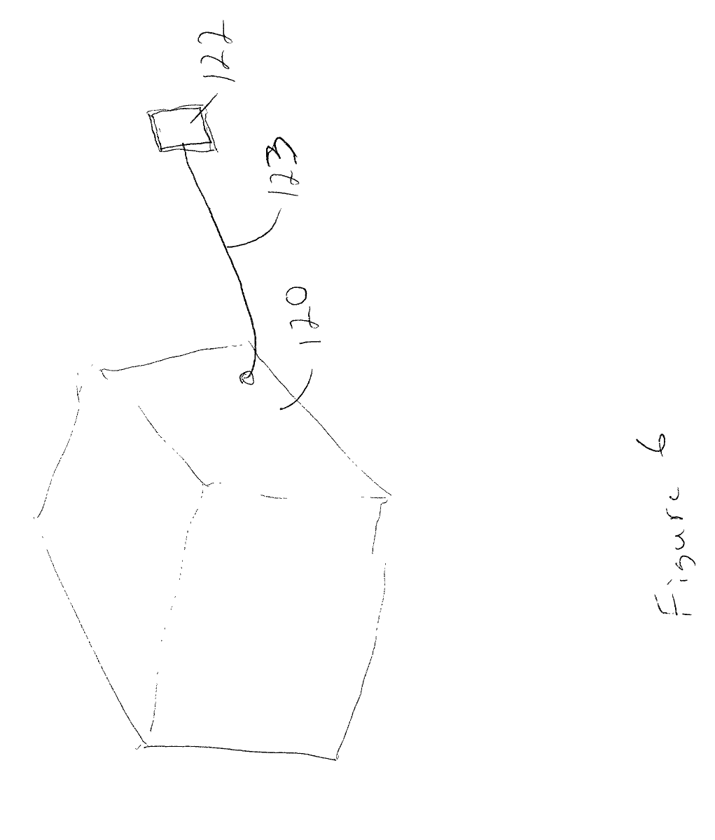

FIG. 6 illustrates yet another alternate exemplary embodiment of the present invention wherein a new digital set top box 120 includes a repeating element 122 for repeating transmissions of channel selection information received by the digital set top box to the corresponding appropriate infrared remote control transmission signals for use by an existing analog conversion box.

Advantageously, in this embodiment, the digital set top box need not be specifically manufactured for a corresponding existing analog set top box. Rather, the digital set top box housing can be dimensioned to virtually any size or shape desired by the manufacturer. The digital set top box 120 includes an output line 123 connected to the infrared signal generating element 122. This exemplary embodiment is much more flexible than the embodiment described above.

Specifically, in order to the compatible with any existing analog hardware, either the user or the manufacturer simply designates the manufacturer or type of analog set-top box with which the digital conversion unit will be working. The analog set-top box need not be positioned within the new digital box. Repeating element 122 transfers the necessary signals to the analog box. The digital set-top box includes a memory unit which provides information concerning the various infrared remote control signaling protocols utilized by the various analog set-top box manufactures. As a result, based on information relating to the particular analog set-top box with which the digital set-top box will be operating allows the unit to transmit the necessary analog set-top box control signals so that a user may readily use the existing analog hardware for viewing analog channels.

In utilizing this exemplary embodiment, the user or some other individual, simply designates the manufacturer or other information which indicates the appropriate infrared signal transmission protocol for the existing analog set top box. As noted, the digital set top box includes a memory unit which provides correlation between received infrared transmission signals from a remote control unit which are processed by the digital set top box into the corresponding appropriate analog signals for controlling the analog set top box. As a result, a user is able to use a single remote control for the purpose of controlling the digital set top box.

In accordance with another feature of the present invention, users are able to view the programming guide information provided in digital cable transmissions. Those skilled in the art will recognize that the programming guide information which is included with typical digital cable transmissions, may be decoded by the digital set top box portion. Accordingly, when a user selects this information for viewing, it is necessary for the device to automatically switch from an existing analog programming presentation through the smart switch discussed above to present programming guide information on a user display.

In order to accomplish presentation of the programming guide information, whenever a user selects the programming guide information for viewing, the system smart switch described above automatically connects an output from the digital set-top box for viewing by the television. In alternate exemplary embodiment, the digital set-top box may also included circuitry for converting the programming guide image information in NTSC format so that this information will be readily available for viewing at anytime.

In a similar manner, the Internet browsing and other interactive functionality can be achieved in the same way. Therefore, this invention will enable the combined analog and digital set top boxes to provide exactly the same functionality as an integrated analog-digital set top box that is being deployed right now.

It is contemplated that a variety of substitutions and/or modifications of the systems methods described herein may be made but which will nevertheless accomplished similar results through utilization of the fundamental technology of the invention. Accordingly, the invention should only be limited by the scope of the appended claims.

I claim:

1. A system for selectively connecting signal outputs from an analog and a digital converter unit comprising:
a switch;
a first analog decoder having at least one output connected to an input of the switch;
a first digital decoder having at least one output connected to an input of the switch;
a switch controller connected to the switch; and
wherein the switch controller is programmed to selectively connect either the analog decoder or the digital decoder as a source of a primary switch output depending on a user specified channel selection.

2. The system for selectively connecting signal outputs from an analog and a digital converter unit of claim 1, further comprising a memory associated with the switch controller which provides a correlation between user channel selection and a switch setting.

3. The system for selectively connecting signal outputs from an analog and a digital converter unit w herein the switch has a secondary output which is connected to either the first analog decoder or the first digital decoder depending upon whichever one is not selected as the primary switch output.

4. The system for selectively connecting signal outputs from an analog and a digital converter unit of claim 2, wherein the memory is a database.

5. The system for selectively connecting signal outputs from an analog and a digital converter unit of claim 2, wherein the memory is a linked list.

6. A method for selectively connecting signal outputs from an analog and a digital converter unit comprising the steps of:
providing a switch having a first input or set of inputs connected to a first analog decoder and a second input or set of inputs connected to a first digital decoder;
providing a switch controller connected to the switch; and
determining a position of the switch based on a user specified channel selection.

7. The method for selectively connecting signal outputs from an analog and a digital converter unit of claim 6, further comprising a step of providing a memory associated with the switch controller which contains information that provides a correlation between user channel selection and a switch setting.

8. The method for selectively connecting signal outputs from an analog and a digital converter unit of claim 6, further comprising a step of connecting a secondary output of the switch to either the first analog decoder or the first digital decoder depending upon whichever one is not selected as the primary switch output.

9. The system for selectively connecting signal outputs from an analog and a digital converter unit of claim 7, wherein the memory is a database.

10. The system for selectively connecting signal outputs from an analog and a digital converter unit of claim 7, wherein the memory is a linked list.
